(19) United States
(12) Patent Application Publication
(10) Pub. No.: US 2026/0068329 A1
(43) Pub. Date: Mar. 5, 2026

(54) ELECTROSTATIC DISCHARGE PROTECTION DEVICE

(71) Applicant: Infineon Technologies Austria AG, Villach (AT)

(72) Inventors: Gernot Langguth, Oberhaching (DE); Janina Roemer, München (DE); Christian Cornelius Russ, Diedorf (DE)

(21) Appl. No.: 18/817,893

(22) Filed: Aug. 28, 2024

(51) Int. Cl. H01L 27/02; H01L 29/778; H01L 29/872

(52) U.S. Cl. CPC H10D 89/819; H10D 1/474; H10D 8/60; H10D 30/47; H10D 89/931

(57) ABSTRACT

An ESD (electrostatic discharge) protection device includes a first enhancement mode HEMT (high-electron-mobility transistor) electrically connected between a protected node and a grounded node, and an RC network electrically connected between the protected node and the grounded node, The time constant of the RC network is set such that a gate of the first enhancement mode HEMT is pulled up to turn on the first enhancement mode HEMT for positive transient pulses at the protected node having a rise time less than the time constant of the RC network. The first enhancement mode HEMT is configured to shunt the protected node to the grounded node when on.

### BACKGROUND

ESD (electrostatic discharge) protection for GaN (gallium nitride) ICs (integrated circuits) such as power switches and RF applications are required to meet a multitude of different ESD and functional requirements. For example, GaN ICs must have high (drain-source) blocking voltages for compliance with functional requirements. In power GaN technologies, blocking voltage requirements may be up to 650V or 1200V or higher. Forward and reverse protection capability is also required for GaN ICs. When utilizing self-protecting ESD techniques, no reliability issue should arise in the functional transistor device after an ESD event. Conventional ESD protection techniques for GaN ICs lack support for high blocking voltages under normal operating conditions in combination with low ESD clamping voltages.

Therefore, there is a need for improved ESD protection techniques for GaN ICs.

### SUMMARY

According to an embodiment of an ESD (electrostatic discharge) protection device, the ESD protection device comprises: a first enhancement mode HEMT (high-electron-mobility transistor) electrically connected between a protected node and a grounded node; and an RC network electrically connected between the protected node and the grounded node, wherein a time constant of the RC network is set such that a gate of the first enhancement mode HEMT is pulled up to turn on the first enhancement mode HEMT for positive transient pulses at the protected node having a rise time less than the time constant of the RC network, wherein the first enhancement mode HEMT is configured to shunt the protected node to the grounded node when on.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a schematic diagram of an embodiment of the ESD protection device.

FIG. 2 illustrates the time constant feature of an RC network included in the ESD protection device.

FIGS. 3 through 7 illustrate respective schematic diagrams of the ESD protection device, according to additional embodiments.

FIGS. 8 through 13 illustrate different circuit schematic implementations of the ESD protection device, according to additional embodiments.

FIG. 14 illustrates a schematic implementation of a system-in-package that includes the ESD protection device in a first semiconductor die and a deactivation circuit in a second semiconductor die co-packaged with the first semiconductor die, according to an embodiment.

FIGS. 15 and 16 illustrate different circuit schematic implementations of the ESD protection device and that provide reverse blocking capability for symmetric operation, according to additional embodiments.

### DETAILED DESCRIPTION

Embodiments described herein provide an ESD (electrostatic discharge) protection device that includes an enhancement mode HEMT (high electron mobility transistor) and an RC network. The enhancement mode HEMT is configured to shunt a protected node to a grounded node when the enhancement mode HEMT is on. The time constant of the RC network is set so as to differentiate between normal operation and ESD events, such that a gate of the enhancement mode HEMT is pulled up to turn on the enhancement mode HEMT for positive ESD pulses at the protected node. The enhancement mode HEMT shunts positive ESD pulses to the grounded node when on. Additional protection circuity such as a diode device may be provided for shunting negative ESD pulses to the grounded node.

The ESD protection device described herein has dynamic triggering to ensure a high blocking voltage during normal operation, e.g., up to 650V, 1200V or higher. The ESD protection device described herein also has a low clamping voltage during ESD events, enables bi-directional protection capability at high area-efficiency, and can be implemented without adding extra devices to GaN technology.

Described next with reference to the figures are embodiments of the ESD protection device.

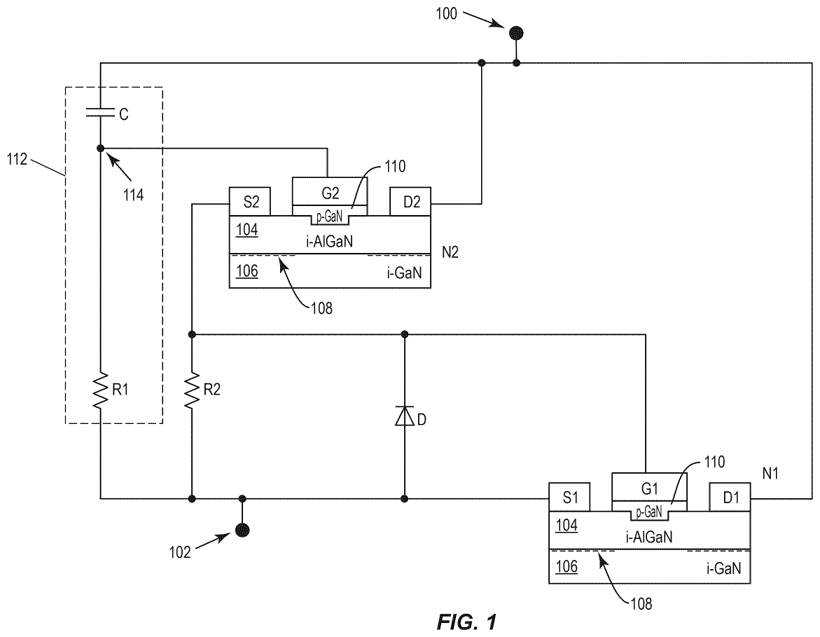

FIG. 1 illustrates a schematic diagram of an embodiment of the ESD protection device. The ESD protection device includes a first enhancement mode HEMT N1 electrically connected between a protected node 100 and a grounded node 102. Enhancement mode transistor devices are off at zero gate-source voltage (Vgs). An NMOS enhancement mode transistor device is turned on by pulling the gate voltage higher than the source voltage. Conversely, a PMOS enhancement mode transistor device is turned on by pulling the gate voltage lower than the source voltage. The first enhancement mode HEMT N1 is a field-effect transistor having a heterojunction between two materials with different band gap energies as the channel instead of a doped region.

In one embodiment, the first enhancement mode HEMT N1 is a GaN-based HEMT where the heterojunction is formed by an AlGaN barrier 104 on a GaN buffer 106 and a two-dimensional electron gas (2DEG) arises at the interface between the AlGaN barrier 104 and the GaN buffer 106. The 2DEG forms the channel of the device instead of a doped region, which forms the channel in a conventional MOSFET device. Similar principles may be utilized to select buffer and barrier layers that form a two-dimensional hole gas (2DHG) as the channel of the device. A 2DEG or a 2DHG is generally referred to as a two-dimensional carrier gas 108. Without further measures, the heterojunction configuration leads to a self-conducting, i.e., normally-on transistor device. To yield an enhancement mode device, measures must be taken to prevent the channel region of an HEMT from being in a conductive state in the absence of a positive gate voltage.

For example, in FIG. 1, the first enhancement mode HEMT N1 includes a recessed p-GaN gate 110 that disrupts the two-dimensional carrier gas 108 between the source S1 and the drain D1 of the first enhancement mode HEMT N1. Other measures may be taken to implement normally-off functionality and other heterojunction layer compositions (heterostructures) may be used to form the first enhancement mode HEMT N1 such as, e.g., GaAs/AlGaAs. For example, a normally-on HEMT with a pulldown circuit can be used to form a switch device that is normally-off. Any kind of stacking of HEMTs may be utilized to achieve e.g. higher breakdown voltage.

In FIG. 1, the ESD protection device also includes an RC network 112. The RC network 112 is electrically connected between the protected node 100 and the grounded node 102. In FIG. 1, the RC network 112 includes a capacitor C and a first resistor R1 in series between the protected node 100 and the grounded node 102. The protected node 100 is a node that is to be protected from ESD events and the grounded node 102 provides a discharge path for ESD pulses.

The RC network 112 has a time constant T_RC which is the time required to charge the capacitor C of the RC network 112, through the first resistor R1 of the RC network 112, from an initial charge voltage of zero to approximately 63.2% of the value of an applied voltage at the protected node 100, or to discharge the capacitor C through the first resistor R1 to approximately 36.8% of its final charge voltage. The time constant T_RC of the RC network 112 is set such that the gate G1 of the first enhancement mode HEMT N1 is pulled up to turn on the first enhancement mode HEMT N1 for positive transient pulses at the protected node 100 having a rise time Tr less than the time constant T_RC of the RC network 112.

As explained above, the time constant T_RC of the RC network 112 may be set longer than the duration of an entire ESD pulse, to differentiate between expected (safe) transient pulses associated with normal operation and destructive ESD pulses. This way, the ESD protection device activates the shunting function only for ESD pulses and (safe) transient pulses associated with normal operation are permitted at the protected node 100.

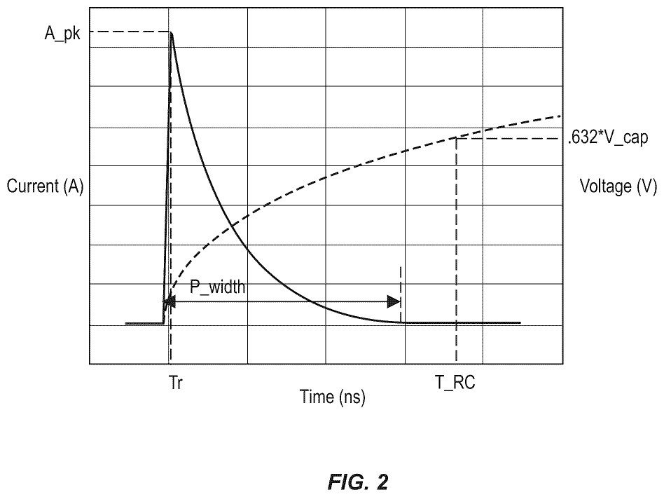

FIG. 2 illustrates the time constant feature of the RC network 112 included in the ESD protection device. FIG. 2 also shows an ESD current pulse during an HBM (human body model) discharge event. The HBM device-level test is one model for characterizing the susceptibility of an electronic component to ESD damage and simulates an electrical discharge of a human to an electronic component. Other common ESD device-level tests are the MM (machine model) device-level test that simulates an electrically charged machine discharging into an electronic component after contact is made, and the CDM (charged device model) device-level test that simulates an electrically charged IC coming into contact with a grounded conductor.

As shown in FIG. 2, the rise time Tr of the ESD pulse is the amount of time that passes before the peak current pulse level A_pk is reached. The rise time Tr of the ESD pulse is less than the time constant T_RC of the RC network 112. The width P_width of the ESD pulse also may be less than the time constant T_RC of the RC network 112, as shown in FIG. 2. For HBM discharge events, the rise time Tr is in a range of about 2 to 10 ns and the pulse width P_width is approximately 150 ns. For MM discharge events, the rise time Tr is approximately 1 ns and the pulse width P_width is approximately 80 ns. For CDM discharge events, the rise time Tr is less than 400 ps and the pulse width P_width is approximately 1 ns. The time constant T_RC of the RC network 112 may be set so that one or more types of ESD events are safely discharged to the grounded node 102, ensuring any device connected to the protected node 100 is not subjected to the destructive energy of an ESD pulse. In one embodiment, the time constant T_RC of the RC network 112 is in a range of 20 ns to 500 ns, e.g., in a range of 50 to 150 ns.

By setting the time constant T_RC of the RC network 112 such that the gate G1 of the first enhancement mode HEMT N1 is pulled up for a positive transient pulse at the protected node having a rise time Tr less than T_RC, the first enhancement mode HEMT N1 turns on to safely shunt the positive transient pulse to the grounded node 102. When the time constant T_RC of the RC network 112 expires, the first resistor R1 of the RC network 112 pulls down the capacitor C of the RC network 112 enough to turn off the first enhancement mode HEMT N1. Accordingly, the ESD protection device operates as a voltage clamp, by clamping the protected node 100 to a safe voltage level during ESD events. That is, the time constant T_RC of the RC network 112 is selected such that when an ESD pulse occurs on the node 100 protected by the ESD protection device, the first enhancement mode HEMT N1 turns on and shunts the protected node 100 to the grounded node 102.

In FIG. 1, the ESD protection device also includes a second enhancement mode HEMT N2 electrically connected between the protected node 100 and the gate G1 of the first enhancement mode HEMT N1 in a source-follower configuration. In one embodiment, the second enhancement mode HEMT N2 is smaller than the first enhancement mode HEMT N1.

The first and second enhancement mode HEMTs N1, N2 may be integrated on the same semiconductor die using the same semiconductor technology (e.g., GaN). The second enhancement mode HEMT N2 may have the same heterojunction structure as the first enhancement mode HEMT N1, as shown in FIG. 1. The first and second enhancement mode HEMTs N1, N2 may be formed on separate dies that use the same or different semiconductor technologies.

In FIG. 1, the first and second enhancement mode HEMTs N1, N2 are both shown as symmetric devices. That is, both enhancement mode HEMTs N1, N2 have the same spacing between the gate G1/G2 and the drain D1/D2 as between the gate G1/G2 and the source S1/S2. To accommodate higher drain blocking voltages, one or both of the enhancement mode HEMTs N1, N2 instead may have an asymmetric configuration whereby the drain-sided device dimensions are extended and a field plate such as a p-GaN field plate is provided on the drain side of the device. According to such an asymmetric configuration, one or both of the enhancement mode HEMTs N1, N2 may have a larger spacing between the gate G1/G2 and the drain D1/D2 than between the gate G1/G2 and the source S1/S2.

A second resistor R2 may be provided for electrically connecting both the gate G1 of the first enhancement mode HEMT N1 and the source S2 of the second enhancement mode HEMT N2 to the grounded node 102. The second resistor R2 is a bias resistor that generates a gate bias voltage during ESD events.

In FIG. 1, the gate G1 of the first enhancement mode HEMT N1 is electrically connected to the source S2 of the second enhancement mode HEMT N2 and the gate G2 of the second enhancement mode HEMT N2 is electrically connected to a timer node 114 between the capacitor C and the first resistor R1 of the RC network 112. The time constant T_RC of the RC network 112 is set such that the gate G2 of the second enhancement mode HEMT N2 is pulled up through the RC network 112 to turn on both the second enhancement mode HEMT N2 and the first enhancement mode HEMT N1 for positive transient pulses at the protected node 100 having a rise time Tr less than the time constant T_RC of the RC network 112.

In more detail, the fast rising edge (high dV/dt) of an ESD pulse pulls up the gate G2 of the second enhancement mode HEMT N2 which acts as an amplification device. Once the second enhancement mode HEMT N2 is on, the gate G1 of the first enhancement mode HEMT N1 is biased high, too, thus shunting the energy of the ESD pulse to the grounded node 102. The first resistor and the capacitor C of the RC network 112 cause a time delay so that the second enhancement mode HEMT N2 remains on for times t<T_RC=C*R1, where T_RC may be on the order of the ESD pulse width P_width. During normal circuit operation, with safe (expected) transients slower than ESD pulses, the capacitor C is charged and the first resistor R1 pulls the gate G1 of the first enhancement mode HEMT N1 low to turn HEMT N1 off. In addition, the second resistor R2 acts as a pull-down resistor, so that the first enhancement mode HEMT N1 is in the off condition.

For ESD stress of the opposite polarity, i.e., the protected node 100 is stressed negatively with respect to the grounded node 102, a diode device D may be provided for signaling to the gate G1 of the first enhancement mode HEMT N1 which opens in the reverse direction (i.e. source S1 and drain D1 are exchanged in their functionality), making use of the unipolar properties of HEMT technology. For example, if a positive ESD pulse occurs on the grounded node 102 and the protected node 100 is grounded, the diode device D would pull up the gate G1 of the first enhancement mode HEMT N1 and the drain and source assignments of the first enhancement mode HEMT N1 would switch, thus turning on the first enhancement mode HEMT N1 in the reverse direction.

In FIG. 1, the anode of the diode device D is electrically connected to the grounded node 100 and the cathode of the diode device D is electrically connected to the gate G1 of the first enhancement mode HEMT N1. In this configuration, the diode device D pulls up the gate G1 of the first enhancement mode HEMT N1 to turn on the first enhancement mode HEMT N1 for negative transient pulses. That is, static triggering is used to turn on the first enhancement mode HEMT N1 for ESD pulses having negative polarity, where the voltage polarity of a transient pulse is determined relative to the protected node 100.

In FIG. 1, the resistor R1 and the capacitor C of the RC network 112 that provide protection against ESD pulses having positive polarity and the diode device D that provides protection against ESD pulses having negative polarity are shown with corresponding circuit symbols. The resistors R1, R2 each may be implemented as a two-dimensional electron gas, as a p-GaN material, or may comprise tantalum nitride or another type of metallic material or a semiconductor material. Still other compositions and configurations are contemplated for the resistors R1, R2. For example, the resistors R1, R2 each may be implemented using a GaN HEMT in the off condition, with the leakage current adjusted accordingly, or a normally-on transistor could be used as part of the time constant circuit.

The capacitor C of the RC network 112 should have enough capacitance to drive the second enhancement mode HEMT N2, which is less capacitance than what would be needed to directly drive the first (shunt) enhancement mode HEMT N1. In this case, an amplification effect is utilized as part of the N2, N1 source-follower configuration shown in FIG. 1. The capacitor C may be implemented as a metal-metal sandwich or lateral metal-metal capacitor. As such, the capacitor C may also comprise copper layers (e.g., TiN/Ta/Cu and TiW/Cu) and inter-metal dielectrics. If a deposited dielectric is available for the transistor gate stack (instead of Schottky gate), the gate dielectric could be used to implement the capacitor C, e.g., as MIS (metal-insulator-semiconductor) gate, or a normally-on transistor device could be used as the capacitor C. In another example, one electrode of the capacitor C can be implemented as a 2DEG, the dielectric can be implemented as an AlGaN barrier, and the other electrode can be implemented as an overlying metal.

The diode device D that provides protection against ESD pulses having negative polarity may be implemented as an enhancement mode HEMT having a gate and a source electrically connected to the grounded node 102 and a drain electrically connected to the gate G1 of the first enhancement mode HEMT N1. In another embodiment, the diode device D is implemented as a Schottky diode. Still other configurations are contemplated for the diode device D.

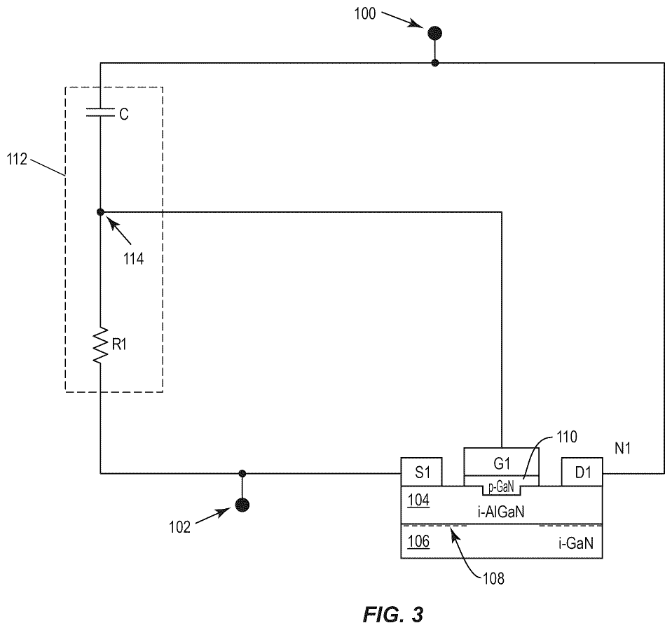

FIG. 3 illustrates a schematic diagram of the ESD protection device, according to another embodiment. In FIG. 3, the second resistor R2 and the second enhancement mode HEMT N2, which collectively form an amplifier stage, are omitted from the ESD protection device. Also, the gate G1 of the first enhancement mode HEMT N1 is electrically connected to the timer node 114 between the capacitor C and the first resistor R1 of the RC network 112. According to this embodiment, the timer node formed by the capacitor C and the first resistor R1 of the RC network 112 is directly connected to the main shunt device formed by the first enhancement mode HEMT N1. As explained above, the resistor R1 may be implemented as a two-dimensional electron gas, as a p-GaN material, may comprise tantalum nitride or another type of metallic material or semiconductor material, etc.

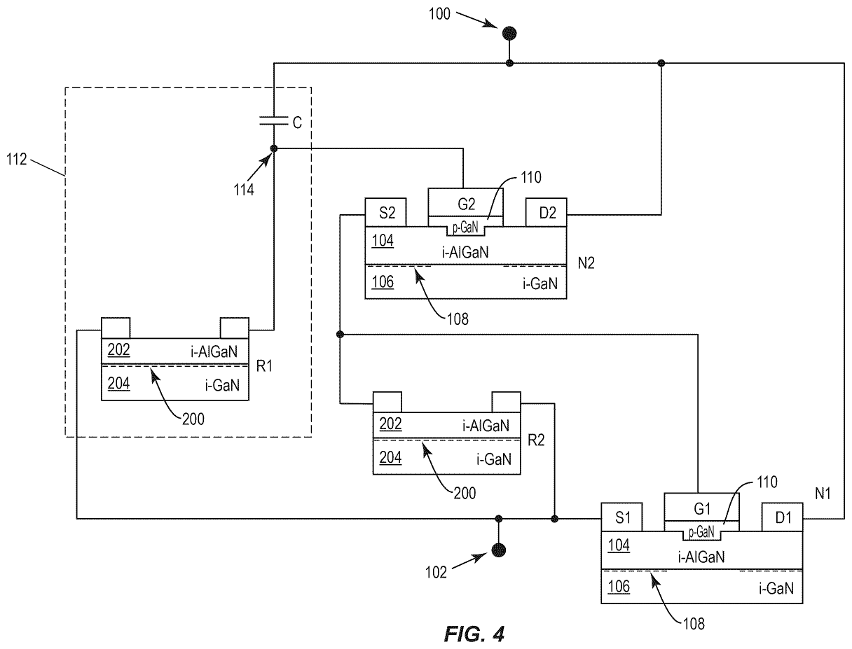

FIG. 4 illustrates another embodiment of the ESD protection device, where the resistors R1, R2 are each shown implemented as a two-dimensional electron gas 200. The two-dimensional electron gas 200 may arise at the interface between an AlGaN barrier 202 on a GaN buffer 204, for example.

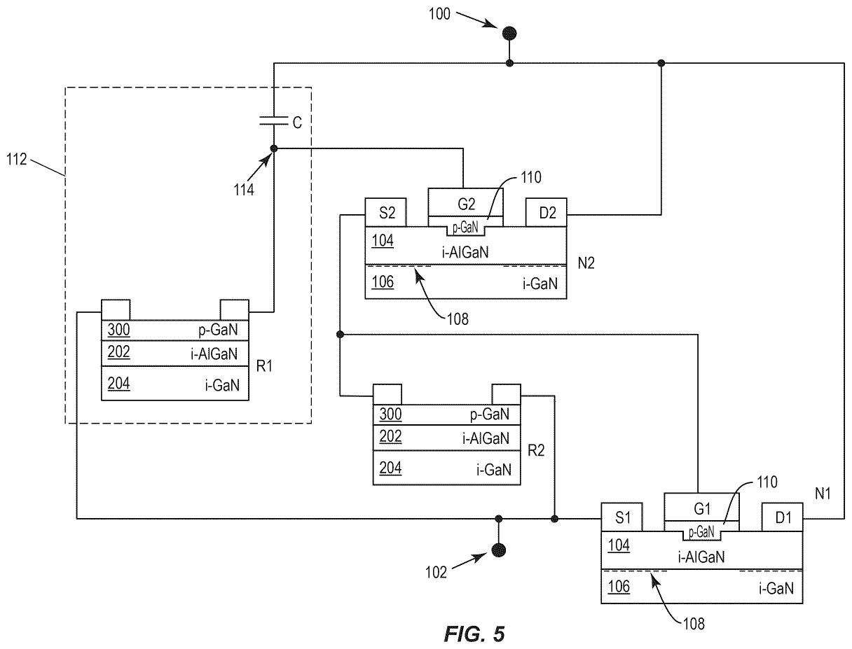

FIG. 5 illustrates another embodiment of the ESD protection device, where the resistors R1, R2 are each shown implemented as a p-GaN material 300. As explained above, still other compositions and configurations are contemplated for the resistors R1, R2. For example, the resistors R1, R2 may each comprise tantalum nitride or another type of metallic material or semiconductor material.

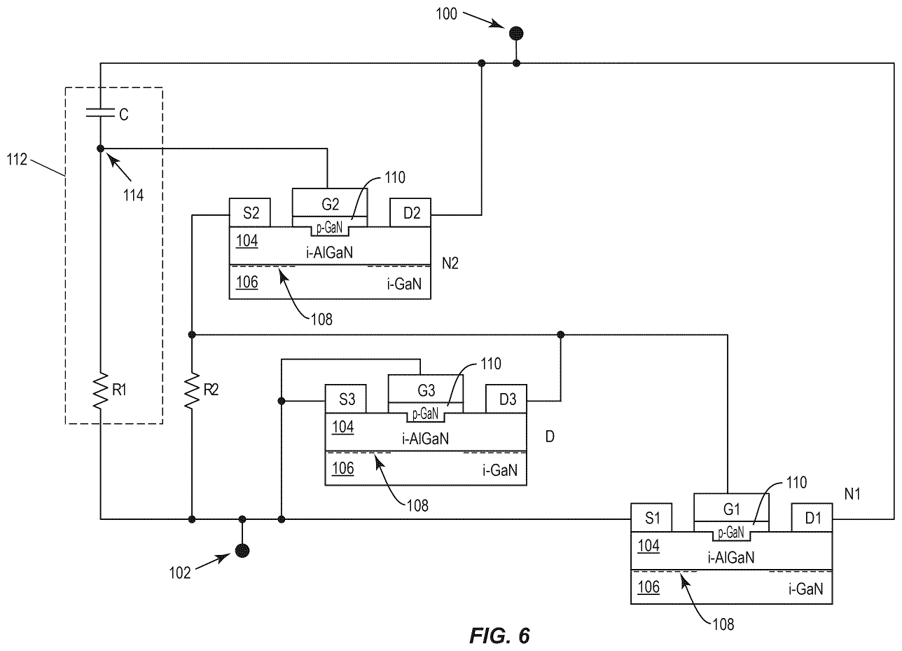

FIG. 6 illustrates another embodiment of the ESD protection device, where the diode device D that provides protection against ESD pulses having negative polarity is shown implemented as an enhancement mode HEMT. The gate G3 and the source S3 of the diode device enhancement mode HEMT are electrically connected to the grounded node 102. The drain D3 of the diode device enhancement mode HEMT is electrically connected to the gate G1 of the first enhancement mode HEMT N1. According to this embodiment, the diode device D is implemented as a gate-grounded HEMT device acting as a diode that provides a positive gate bias to the first enhancement mode HEMT N1 for negative transient pulses. The diode device enhancement mode HEMT may have the same heterojunction structure as the first enhancement mode HEMT N1, as shown in FIG. 6.

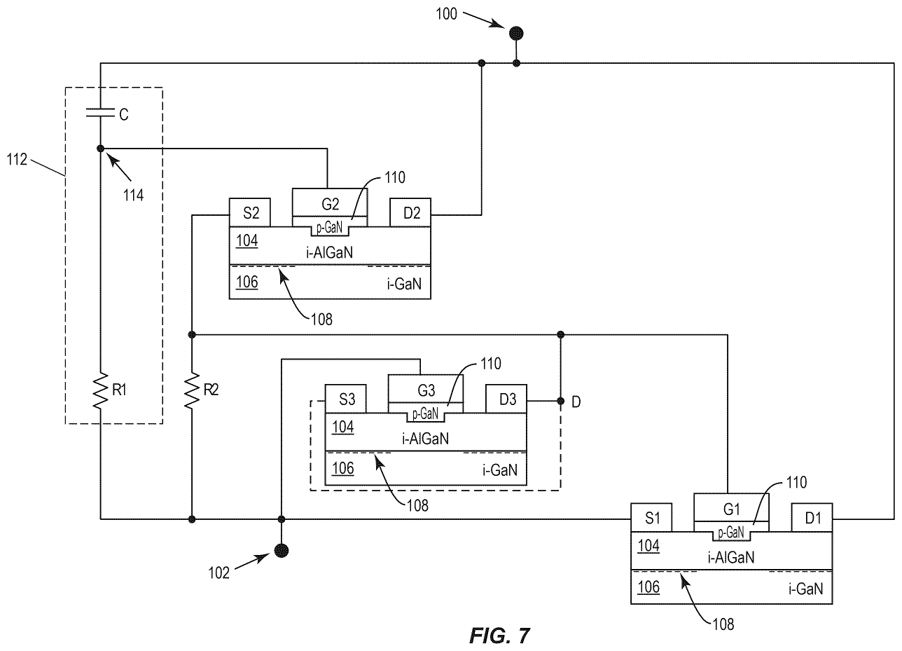

FIG. 7 illustrates another embodiment of the ESD protection device, where the diode device D that provides protection against ESD pulses having negative polarity is shown implemented as a Schottky diode. According to this embodiment, the drain D3 and/or the source S3 of the Schottky diode device is electrically connected to the gate G1 of the first enhancement mode HEMT N1 and to the source S2 of the second enhancement mode HEMT N2. The g-GaN gate 110 is electrically connected to the grounded node 102.

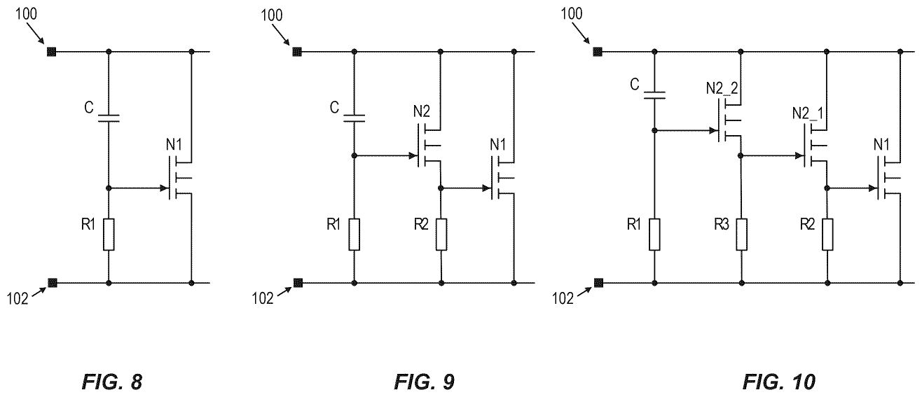

FIGS. 8 through 13 illustrate different circuit schematic implementations of the ESD protection device. The circuit schematic of FIG. 8 corresponds to the ESD protection device embodiment illustrated in FIG. 3 with no source follower stage. The circuit schematic of FIG. 9 corresponds to the ESD protection device embodiment illustrated in FIG. 1 with a single source follower stage. The circuit schematic of FIG. 10 illustrates an embodiment which utilizes two (2) source followers N2_1 and N2_2. According to this embodiment, the RC network 112 includes a third resistor R3 through which the source of the second source follower N2_2 is electrically connected to the grounded node 102. Further according to this embodiment, the typical threshold voltage is about 1.5V which can be neglected because two source follower stages are used.

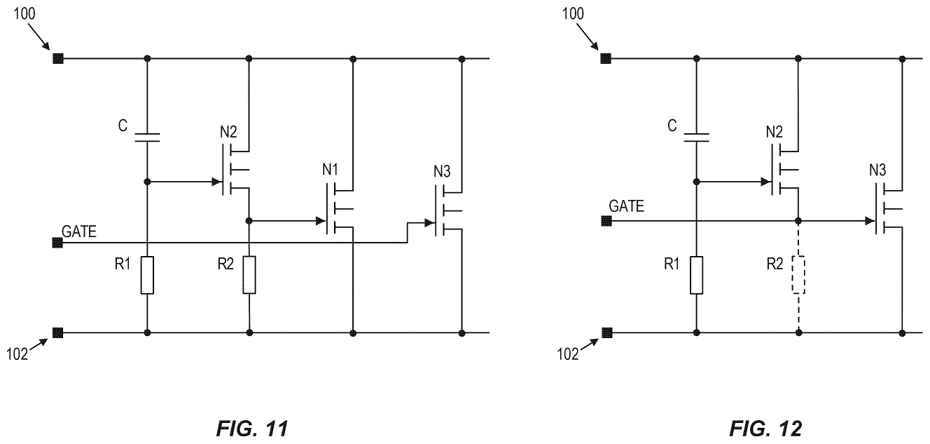

FIG. 11 illustrates a circuit schematic implementation of the ESD protection device for protecting a HEMT device N3 having a gate terminal GATE. The circuit schematic of FIG. 9 corresponds to the ESD protection device embodiment illustrated in FIG. 1 with a single source follower stage. The first and second enhancement mode HEMTs N1, N2 of the ESD protection device are normally-off HEMT devices. The HEMT device N3 being protected can be a normally-off or normally-on device. The main application of the voltage clamp by the ESD protection device is protection from drain-to-source of the HEMT device N3 being protected. For protection from gate-to-source, the maximum allowed gate-source voltage may be about 5V because of the Schottky diode between the gate and the 2DEG. The gate may have some level of self-protection because of capacitive damping effects and the Schottky junction.

FIG. 12 illustrates another circuit schematic implementation of the ESD protection device for protecting HEMT device N3. The circuit schematics of FIGS. 11 and 12 are similar, with the difference being that in FIG. 12, the HEMT device N3 being protected and the first enhancement mode HEMT N1 of the ESD protection device are merged together in a self-protected configuration. That is, the functionality of the first enhancement mode HEMT N1 of the ESD protection device is merged into the HEMT device N3 being protected.

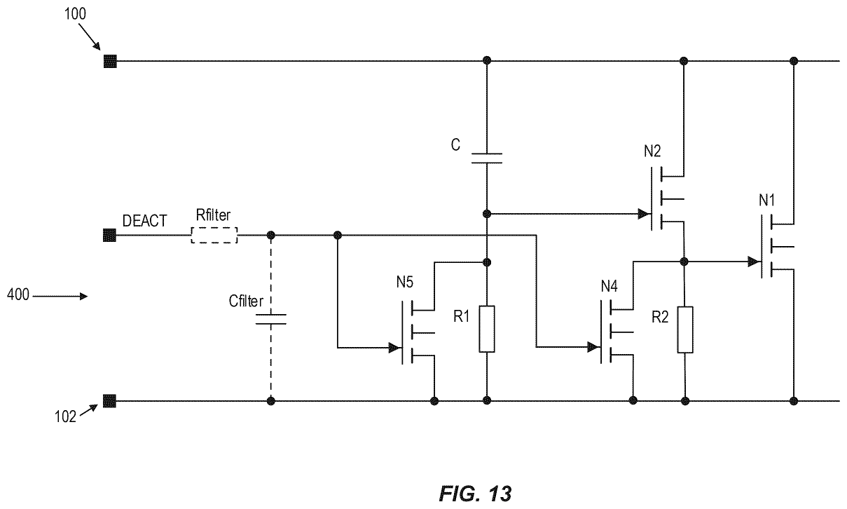

FIG. 13 illustrates a circuit schematic implementation of the ESD protection device, according to another embodiment. In FIG. 13, the ESD protection device further includes a deactivation circuit 400 that deactivates the first enhancement mode HEMT N1 in response to a deactivation signal DEACT. If a fast transient event that is part of normal operation occurs and has the same or similar rise time profile as an ESD event, the first enhancement mode HEMT N1 of the ESD protection device will be activated by the RC network 112 unless deactivated. To this end, the deactivation circuit 400 deactivates the voltage clamping functionality of the first enhancement mode HEMT N1 during non-ESD transient events.

In one embodiment, the deactivation circuit 400 is a pulldown device that pulls down the gate G1 of the first enhancement mode HEMT N1 in response to the deactivation signal DEACT. For example, the deactivation circuit may include a normally-off pulldown transistors N4 and/or N5 in parallel with one or both resistors R1, R2, and an RC filter formed by a capacitor Cfilter and a resistor Rfilter. The RC filter Cfilter, Rfilter of the deactivation circuit 400 derives the deactivation signal DEACT from signal activity on the node to be protected 100, or derives the deactivation signal DEACT from other sources of the electronic (sub-)system which indicates an operational state. The time constant of the RC filter Cfilter, Rfilter is set such that the deactivation circuit 400 deactivates the first enhancement mode HEMT N1, via the pulldown devices N4, N5, except during ESD events.

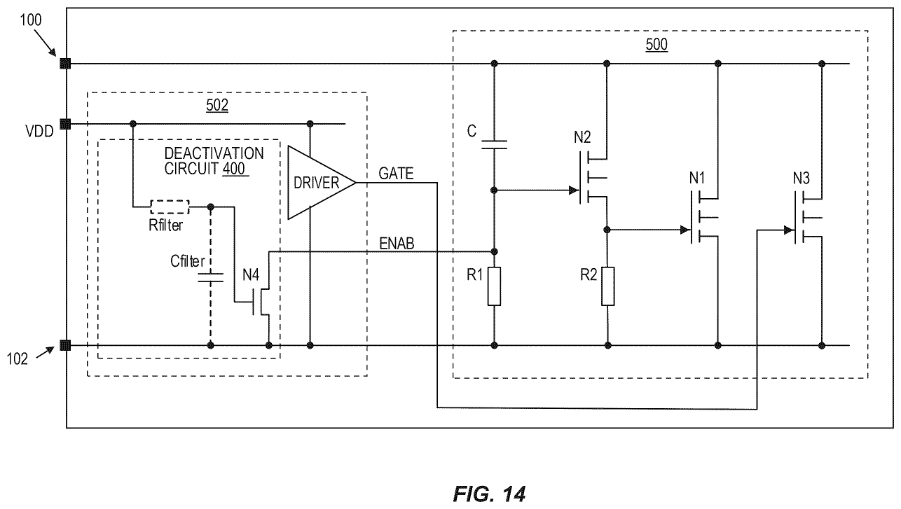

FIG. 14 illustrates a schematic implementation of a system-in-package that includes the ESD protection device in a first semiconductor die 500 such as a GaN die and the deactivation circuit 400 in a second semiconductor die 502 such as a Si die co-packaged with the first semiconductor die 500. The first semiconductor die 500 also includes the device N3 being protected. The gate signal GATE may come from a driver on the second semiconductor die 502, for example. Upon availability of a supply voltage VDD, a pulldown signal ENAB output by the deactivation circuit 400 is low to safely keep the ESD protection device in an off-configuration, making the ESD protection device robust against false triggering by voltage spikes on the supply VDD during normal operation of the device N3 being protected. The RC filter Cfilter, Rfilter of the deactivation circuit 400 ensures that if the deactivation signal DEACT comes from the node to be protected 100, the voltage clamp functions as designed during the 1 μs or less when ESD events typically occur. The time constant of the RC filter Cfilter, Rfilter of the deactivation circuit 400 may be chosen so that voltage clamp is deactivated during normal operation and active during ESD events.

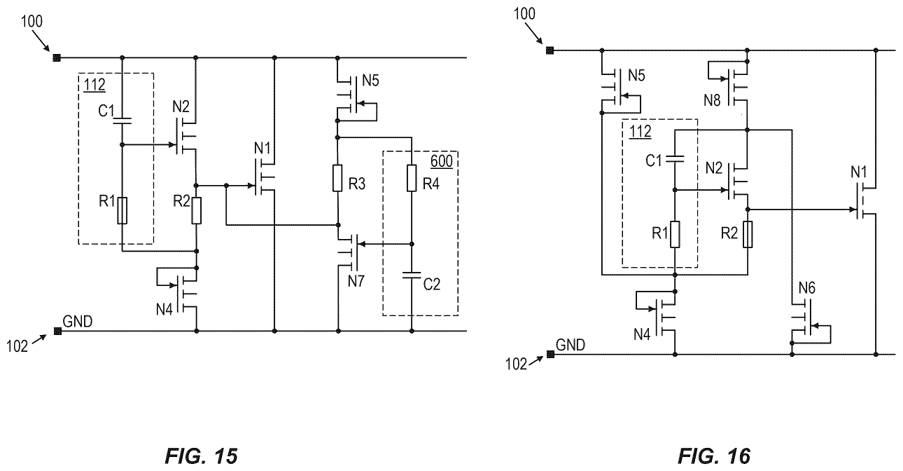

FIGS. 15 and 16 illustrate different circuit schematic implementations of the ESD protection device and that provide reverse blocking capability for symmetric operation. In the absence of a body diode in a GaN HEMT device, the first (shunt) enhancement mode HEMT N1 of the ESD protection device may be employed in a symmetrical manner.

FIG. 15 illustrates symmetrical RC control of the joint shunt. The joint shunt is formed by HEMT N1. HEMTs N4 and N5 ensure proper timer operation and gate bias for HEMT N1 for both positive and negative pulse polarities. HEMTs N4 and N5 block in both directions for DC and slow signals. The ESD protection device also includes a third enhancement mode HEMT N7 and an additional RC network 600 formed by a capacitor C2 and resistor R4. Resistor R3 generates a bias voltage for the gate of HEMT N1. The resistors R3 and R4 are electrically connected to the protected node 100 through gated diode device N5, and the resistors R1 and R2 are electrically connected to the grounded node 102 through gated diode device N4.

The time constant of the additional RC network 600 is set such that the gate of the third enhancement mode HEMT N7 is pulled up to turn on the first enhancement mode HEMT N1 for negative transient pulses at the protected node 100 having a rise time less than the time constant of the additional RC network 600. The first enhancement mode HEMT N1 is configured to shunt the protected node 100 to the grounded node 102 when on.

FIG. 16 shows an alternative version, where four (4) diode-configured HEMT devices N4, N5, N6, N8 provide a rectifying functionality so that a single RC network 112 and corresponding driver circuit N2, R2 is sufficient. In FIG. 16, the capacitor C of the single RC network 112 and the drain D2 of the second enhancement mode HEMT N2 are electrically connected to the protected node 100 through gated diode device N8 and to the grounded node 102 through gated diode device N6. Also in FIG. 16, the first resistor R1 and the second resistor R2 of the ESD protection device are electrically connected to the grounded node 102 through gated diode device N4 and to the protected node 100 through gated diode device N5. That is, for either positive or negative stress polarity at the protected node 100, the single RC network 112 and the corresponding driver circuit N2, R2 are always biased such the capacitor C1 and drain D2 of HEMT N2 receive a positive voltage and resistors R1 and R2 will be at lower potential. In effect, the gate signal for the main shunt HEMT N1 will be positive with respect to its respective source terminal at low potential according to the ESD stress polarity between the protection node 100 and the grounded node 102. By omitting the second capacitor C2 shown in FIG. 15, an area savings is realized.

With the ESD protection scheme described herein, ESD robustness is attainable at the component level for all pins of HEMT devices and for all ESD stress polarities. The ESD clamp feature may be monolithically integrated in the same technology as any active device HEMT device that requires protection, providing added value because the clamp can also protect the rather sensitive gate terminals. This protection is accomplished without the need for HEMT self-protection capability, which is often not feasible for certain pin combinations and/or voltage polarities. For protection of pins which undergo fast transient noise, the voltage clamp can be deactivated, e.g. as described herein in connection with FIG. 13, to avoid any false triggering under these conditions.

Although the present disclosure is not so limited, the following numbered examples demonstrate one or more aspects of the disclosure.

Example 1. An ESD (electrostatic discharge) protection device, comprising: a first enhancement mode HEMT (high-electron-mobility transistor) electrically connected between a protected node and a grounded node; and an RC network electrically connected between the protected node and the grounded node, wherein a time constant of the RC network is set such that a gate of the first enhancement mode HEMT is pulled up to turn on the first enhancement mode HEMT for positive transient pulses at the protected node having a rise time less than the time constant of the RC network, wherein the first enhancement mode HEMT is configured to shunt the protected node to the grounded node when on.

Example 2. The ESD protection device of example 1, further comprising: a diode device configured to pull up the gate of the first enhancement mode HEMT to turn on the first enhancement mode HEMT for negative transient pulses.

Example 3. The ESD protection device of example 2, wherein the diode device is implemented as an enhancement mode HEMT having a gate and a source electrically connected to the grounded node and a drain electrically connected to the gate of the first enhancement mode HEMT.

Example 4. The ESD protection device of example 2, wherein the diode device is a Schottky diode.

Example 5. The ESD protection device of any of examples 1 through 4, wherein the RC network comprises a capacitor and a resistor in series between the protected node and the grounded node, and wherein the gate of the first enhancement mode HEMT is electrically connected to a node between the capacitor and the resistor.

Example 6. The ESD protection device of example 5, wherein the resistor is implemented as a two-dimensional electron gas.

Example 7. The ESD protection device of example 5, wherein the resistor is implemented as a p-GaN material.

Example 8. The ESD protection device of example 5, wherein the resistor comprises tantalum nitride.

Example 9. The ESD protection device of any of examples 1 through 8, further comprising: a second enhancement mode HEMT electrically connected between the protected node and the gate of the first enhancement mode HEMT in a source-follower configuration, wherein the time constant of the RC network is set such that a gate of the second enhancement mode HEMT is pulled up through the RC network to turn on both the second enhancement mode HEMT and the first enhancement mode HEMT for positive transient pulses at the protected node having a rise time less than the time constant of the RC network.

Example 10. The ESD protection device of example 9, further comprising: a second resistor through which both the gate of the first enhancement mode HEMT and a source of the second enhancement mode HEMT are electrically connected to the grounded node, wherein the RC network comprises a capacitor and a first resistor in series between the protected node and the grounded node, wherein the gate of the first enhancement mode HEMT is electrically connected to the source of the second enhancement mode HEMT, and wherein the gate of the second enhancement mode HEMT is electrically connected to a node between the capacitor and the first resistor.

Example 11. The ESD protection device of example 10, further comprising: a diode device having an anode electrically connected to the grounded node and a cathode electrically connected to the gate of the first enhancement mode HEMT.

Example 12. The ESD protection device of example 10 or 11, wherein the first resistor and the second resistor are each implemented as a two-dimensional electron gas.

Example 13. The ESD protection device of any of examples 10 through 12, wherein the first resistor and the second resistor are each implemented as a p-GaN material.

Example 14. The ESD protection device of any of examples 10 through 12, wherein the first resistor and the second resistor each comprise tantalum nitride.

Example 15. The ESD protection device of any of examples 10 through 14, wherein the capacitor and a drain of the second enhancement mode HEMT are electrically connected to the protected node through a first gated diode device and to the grounded node through a second gated diode device, and wherein the first resistor and the second resistor are electrically connected to the grounded node through a third gated diode device and to the protected node through a fourth gated diode device.

Example 16. The ESD protection device of any of examples 9 through 15, further comprising: a third enhancement mode HEMT; and an additional RC network, wherein a time constant of the additional RC network is set such that a gate of the third enhancement mode HEMT is pulled up to turn on the first enhancement mode HEMT for negative transient pulses at the protected node having a rise time less than the time constant of the additional RC network, wherein the first enhancement mode HEMT is configured to shunt the protected node to the grounded node when on.

Example 17. The ESD protection device of any of examples 9 through 16, wherein the second enhancement mode HEMT is smaller than the first enhancement mode HEMT.

Example 18. The ESD protection device of any of examples 1 through 17, wherein the time constant of the RC network is in a range of 20 ns to 500 ns.

Example 19. The ESD protection device of any of examples 1 through 18, further comprising: a deactivation circuit configured to deactivate the first enhancement mode HEMT in response to a deactivation signal.

Example 20. The ESD protection device of example 19, wherein the deactivation circuit is a pulldown device configured to pull down the gate of the first enhancement mode HEMT in response to the deactivation signal.

Example 21. The ESD protection device of example 19, wherein the deactivation circuit comprises an RC filter configured to derive the deactivation signal from signal activity on the node to be protected, and wherein a time constant of the RC filter is set such that the deactivation circuit deactivates the first enhancement mode HEMT except during ESD events.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An ESD (electrostatic discharge) protection device, comprising:
a first enhancement mode HEMT (high-electron-mobility transistor) electrically connected between a protected node and a grounded node; and
an RC network electrically connected between the protected node and the grounded node,
wherein a time constant of the RC network is set such that a gate of the first enhancement mode HEMT is pulled up to turn on the first enhancement mode HEMT for positive transient pulses at the protected node having a rise time less than the time constant of the RC network,
wherein the first enhancement mode HEMT is configured to shunt the protected node to the grounded node when on.

2. The ESD protection device of claim 1, further comprising:
a diode device configured to pull up the gate of the first enhancement mode HEMT to turn on the first enhancement mode HEMT for negative transient pulses.

3. The ESD protection device of claim 2, wherein the diode device is implemented as an enhancement mode HEMT having a gate and a source electrically connected to the grounded node and a drain electrically connected to the gate of the first enhancement mode HEMT.

4. The ESD protection device of claim 2, wherein the diode device is a Schottky diode.

5. The ESD protection device of claim 1, wherein the RC network comprises a capacitor and a resistor in series between the protected node and the grounded node, and wherein the gate of the first enhancement mode HEMT is electrically connected to a node between the capacitor and the resistor.

6. The ESD protection device of claim 5, wherein the resistor is implemented as a two-dimensional electron gas.

7. The ESD protection device of claim 5, wherein the resistor is implemented as a p-GaN material.

8. The ESD protection device of claim 5, wherein the resistor comprises tantalum nitride.

9. The ESD protection device of claim 1, further comprising:
a second enhancement mode HEMT electrically connected between the protected node and the gate of the first enhancement mode HEMT in a source-follower configuration,
wherein the time constant of the RC network is set such that a gate of the second enhancement mode HEMT is pulled up through the RC network to turn on both the second enhancement mode HEMT and the first enhancement mode HEMT for positive transient pulses at the protected node having a rise time less than the time constant of the RC network.

10. The ESD protection device of claim 9, further comprising:
a second resistor through which both the gate of the first enhancement mode HEMT and a source of the second enhancement mode HEMT are electrically connected to the grounded node,
wherein the RC network comprises a capacitor and a first resistor in series between the protected node and the grounded node,
wherein the gate of the first enhancement mode HEMT is electrically connected to the source of the second enhancement mode HEMT, and
wherein the gate of the second enhancement mode HEMT is electrically connected to a node between the capacitor and the first resistor.

11. The ESD protection device of claim 10, further comprising:
a diode device having an anode electrically connected to the grounded node and a cathode electrically connected to the gate of the first enhancement mode HEMT.

12. The ESD protection device of claim 10, wherein the first resistor and the second resistor are each implemented as a two-dimensional electron gas.

13. The ESD protection device of claim 10, wherein the first resistor and the second resistor are each implemented as a p-GaN material.

14. The ESD protection device of claim 10, wherein the first resistor and the second resistor each comprise tantalum nitride.

15. The ESD protection device of claim 10, wherein the capacitor and a drain of the second enhancement mode HEMT are electrically connected to the protected node through a first gated diode device and to the grounded node through a second gated diode device, and wherein the first resistor and the second resistor are electrically connected to the grounded node through a third gated diode device and to the protected node through a fourth gated diode device.

16. The ESD protection device of claim 9, further comprising:
a third enhancement mode HEMT; and
an additional RC network,
wherein a time constant of the additional RC network is set such that a gate of the third enhancement mode HEMT is pulled up to turn on the first enhancement mode HEMT for negative transient pulses at the protected node having a rise time less than the time constant of the additional RC network, wherein the first enhancement mode HEMT is configured to shunt the protected node to the grounded node when on.

17. The ESD protection device of claim 9, wherein the second enhancement mode HEMT is smaller than the first enhancement mode HEMT.

18. The ESD protection device of claim 1, wherein the time constant of the RC network is in a range of 20 ns to 500 ns.

19. The ESD protection device of claim 1, further comprising:
a deactivation circuit configured to deactivate the first enhancement mode HEMT in response to a deactivation signal.

20. The ESD protection device of claim 19, wherein the deactivation circuit is a pulldown device configured to pull down the gate of the first enhancement mode HEMT in response to the deactivation signal.

21. The ESD protection device of claim 19, wherein the deactivation circuit comprises an RC filter configured to derive the deactivation signal from signal activity on the node to be protected, and wherein a time constant of the RC filter is set such that the deactivation circuit deactivates the first enhancement mode HEMT except during ESD events.
